(19) United States
(12) Patent Application Publication
(10) Pub. No.: US 2012/0012918 A1
(43) Pub. Date: Jan. 19, 2012

(54) SEMICONDUCTOR STRUCTURE AND METHOD FOR MANUFACTURING THE SAME

(76) Inventors: Huilong Zhu, Poughkeepsie, NY (US); Haizhou Yin, Poughkeepsie, NY (US); Zhijiong Luo, Poughkeepsie, NY (US)

(21) Appl. No.: 13/146,882

(22) PCT Filed: Feb. 24, 2011
(86) PCT No.: PCT/CN2011/071250

§ 371 Date: Jul. 28, 2011

(30) Foreign Application Priority Data
May 19, 2010 (CN) 201010181638.1

(51) Int. Cl. H01L 29/788; H01L 21/336

(52) U.S. Cl. 257/316; 438/257; 257/E29.3; 257/E21.422

(57) ABSTRACT

A semiconductor structure and the method for manufacturing the same, wherein the structure comprising a semiconductor substrate: a flash memory device formed on the semiconductor substrate; wherein the flash memory device comprising: a channel region formed on the semiconductor substrate; a gate stack structure formed on the channel region; wherein the gate stack structure comprises: a first gate dielectric layer formed on the channel region; a first conductive layer formed on the first gate dielectric layer; a second gate dielectric layer formed on the first conductive layer; a second conductive layer formed on the second gate dielectric layer; a heavily doped first-conduction-type region and a heavily doped second-conduction-type region at both sides of the channel region respectively, wherein the first conduction type is opposite to the second conduction type in the type of conduction.

### CROSS REFERENCE TO RELATED APPLICATIONS

The present application is a Section 371 National Stage Application of International Application No. PCT/CN2011/071250, filed on Feb. 24, 2011, which claims the priority of Chinese Patent Application No. 201010181638.1, filed on May 19, 2010. The entire disclosures of both the Chinese application and the PCT application are incorporated herein by reference.

### FIELD OF THE INVENTION

The present invention relates to semiconductor manufacturing technology, and particularly to a Tunneling Field Effect Transistor (TFET) structure and a method for manufacturing the same.

### BACKGROUND OF THE INVENTION

As the sizes of Metal Oxide Semiconductor Field Effect Transistors (MOSFETs) are scaled down continuously, the conventional MOSFET structure failed to meet the daily-increasing requirements. Therefore, a TFET structure is introduced to meet the daily-increasing demand for switching performance of devices.

When a certain threshold voltage is applied to the gate of the TFET, potential barrier of the source region and the drain region, which are at both sides of the channel region, will be decreased due to quantum tunneling effect, and whereby the drain region and the source region may be turned on instantly.

With the development of technology, the threshold voltage of the gate is required to be decreased further to meet the increasing need for low power consumption in electronic products.

### SUMMARY OF THE INVENTION

The object of the present invention is to provide a solution to resolve the technical defects mentioned above and achieve a lower VGS of flash memory device.

According to one aspect of the present invention, the present invention will provide a semiconductor structure including: a semiconductor substrate; a flash memory device forming on the semiconductor substrate; wherein the flash memory device includes: a channel region forming on the semiconductor substrate; a gate stack structure forming on the channel region, wherein the gate stack structure includes: a first gate dielectric layer forming on the channel region; a first conductive layer forming on the first gate dielectric layer; a second gate-dielectric layer forming on the first conductive layer; a second conductive layer forming on the second gate dielectric layer; a heavily doped first-conduction-type region and a heavily doped second-conduction-type region at both sides of the channel region respectively, wherein the first conduction type region is opposite to the second conduction type region in the type of conduction.

A method for manufacturing a semiconductor structure is given according to another aspect of the present invention including: providing a semiconductor substrate: forming a gate stack structure on the semiconductor substrate, wherein the gate stack structure includes: a first gate dielectric layer forming on the substrate of the semiconductor; a first conductive layer forming on the first gate dielectric layer; a second gate dielectric layer forming on the first conductive layer; a second conductive layer forming on the second gate dielectric layer; doping heavily at both sides of the gate stack on the semiconductor substrate to form a first-conduction-type region and a second-conduction-type region, wherein the first conduction-type-region is opposite to the second-conduction-type region in the type of conduction.

Optionally, on the basis of the above project, the first gate dielectric layer or the second gate dielectric layer can be made of anyone or a combination from materials such as Al₂O₃, HfO₂, HfSiO, HfSiON, HtTaO, HiTiO, HtZrO, SiO₂ and Si₃N₄.

Optionally, the first conductive layer is made of anyone or a combination from materials such as TiN, TaN, Ti, Ta, Al, Cu, Ci, Ni and polysilicon.

Optionally, the second conductive layer is made of heavily doped first-conduction-type polysilicon or heavily doped second-conduction-type polysilicon, and is opposite to the channel region beneath the gate stack in the type of conduction.

In the embodiment of the present invention, the first conduction type can be p-type, and the second conduction type can be n-type: or the first conduction type can be n-type and the second conduction type can be p-type.

Optionally, a Buried Oxide (BOX) layer is on the semiconductor substrate, a Semiconductor On Insulator (SOI) layer formed on the BOX layer and a channel region formed on the SOI layer. Optionally, the SOI layer has a thickness within the range of 1-10 nm.

The first conduction region and the second conduction region are source region and drain region of the semiconductor structure respectively. The second conductive layer is a control gate and the first conductive layer is a floating gate.

According to the semiconductor structure of the present invention, by applying appropriate bias voltage on the floating gate and the source region and the drain region, quantum tunneling effect will easily occur among the electric charges accumulated on the floating gate because of a drastic decrease in barrier, thereby the device can be switched on/off with a low voltage; and then a low consumption flash memory device can be manufactured.

Additional aspects and advantages of the present invention will be described in following disclosure, part of them will become apparent through the description or the embodiment of the present invention.

### BRIEF DESCRIPTION OF THE DRAWINGS

The above-mentioned and other objectives, features and advantages of the present invention will become clearer through the description with attached drawings. Like reference numerals refer to the like elements throughout the drawings. The attached drawings are not drawn to scale in order for mainly disclosing the purport of the present invention.

FIGS. 1-7 are cross-sectional views of intermediate structures in a method for manufacturing a semiconductor structure according to an embodiment of the present invention;

FIG. 8 is a sectional view of a semiconductor structure according to an embodiment of the present invention; and

FIG. 9 is diagrams of the energy bands corresponding to the semiconductor structure of the embodiment of the present invention.

### DETAILED DESCRIPTION OF THE EMBODIMENTS

The present invention will be described in detail hereunder with reference to embodiments in conjunction with the accompanying drawings.

The following disclosure will provide various kinds of embodiments or examples implementing different kinds of structures of the present invention. Devices and settings in some certain examples will be described in the following disclosure for simplification of the disclosure. Of course, they are only illustrative rather than limiting the present invention. In addition, figures and/or letters can be repeated in different examples. Such repetition is only for simplification and clearness, and does not indicate the relationship among various kinds of embodiments and/or settings discussed. Moreover, the present invention provides various examples of certain techniques and materials, but any skilled person in this art can be aware of the applicability of other techniques and/or usage of other materials. In addition, the structure wherein the first feature is on the second feature can include an embodiment where the first feature is in direct contact with the second feature, and can further include an embodiment where another feature is formed between the first feature and the second feature such that the first feature may not be in direct contact with the second feature.

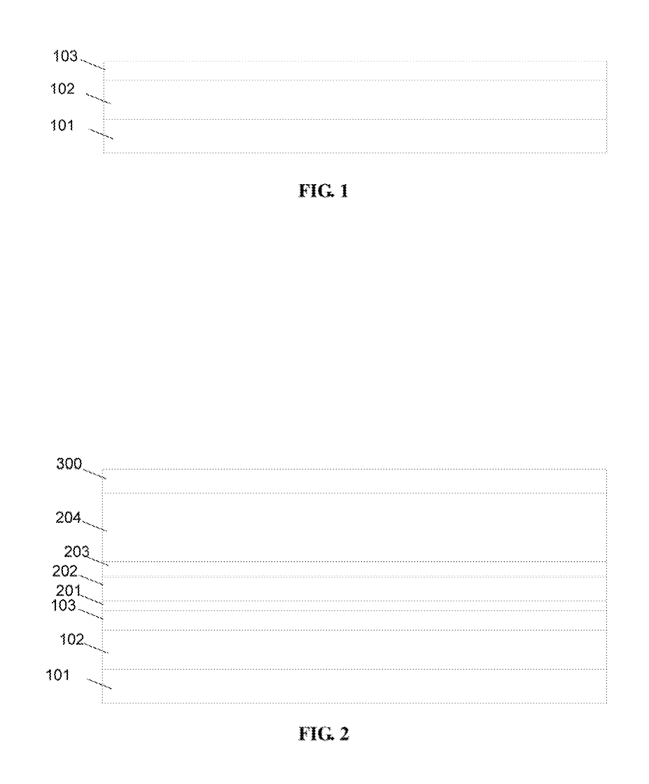

FIGS. 1-7 are cross-sectional views of intermediate structures in a method for manufacturing a semiconductor structure according to an embodiment of the present invention. Each step and intermediate structure formed thereby will he described in detail hereinafter according to the embodiment of the present invention in conjunction with the drawings.

Referring to FIG. 1, a semiconductor substrate 101, such as a doped silicon substrate, a doped germanium substrate or other semiconductor substrates made of III-V compound semiconductor, is provided. In order to achieve the advantages of the embodiment of the present invention, preferably, a buried oxide (BOX) layer 102 may be formed on the semiconductor substrate 101, and a SOI layer 103 may be formed on the BOX layer 102. The SOI layer 103 may have a thickness within the range of 1-10 nm, preferably, 5-10 nm.

The portion of the SOI layer 103 where a gate stack structure will be formed is lightly doped, and the doping may be either n-type or p-type. P-type doping is used in the embodiment.

Referring to FIG. 2, the gate stack structure is formed. Specifically, a first gate dielectric layer 201 is formed on the SOI layer 103. The first dielectric layer 201 may be made of at least one of materials such as Al₂O₃, HfO₂, HfSiO, HfSiON, HfTaO, HMO, HfTiO, SiO₂ and Si₃N₄, preferably, Al₂O₃, and may have a thickness within the range of about 2-5 nm. Then, a first conductive layer 202 is formed on the first gate dielectric layer 201. The conductive layer 202 may be made of at least one of materials such as TiN, TaN, Ti, Ta, Al, Cu, Ci, Ni and polysilicon. Then, a second gate dielectric layer 203 is formed on the first conductive layer 202. The second gate dielectric layer 203 may be made of the same material with that of the first gate dielectric layer 201. The second gate dielectric layer 203 may have a thickness within the range of about 5-20 nm if Si₃N₄ is used, or may have a thickness within the range of about 5-30 nm if Al₂O₃ is used. Then a second conductive layer 204 is formed on the second gate dielectric layer 203. Preferably, the second conductive layer 204 is made of polysilicon and has a thickness within the range of 50-100 nm.

In order to protect the gate stack structure from being damaged during etching of the gate stack, an oxide layer 300 having a thickness of about 10 nm may be formed on the second conductive layer 204. Certainly, a nitride cap layer may also be used to protect the gate stack structure in the etching process.

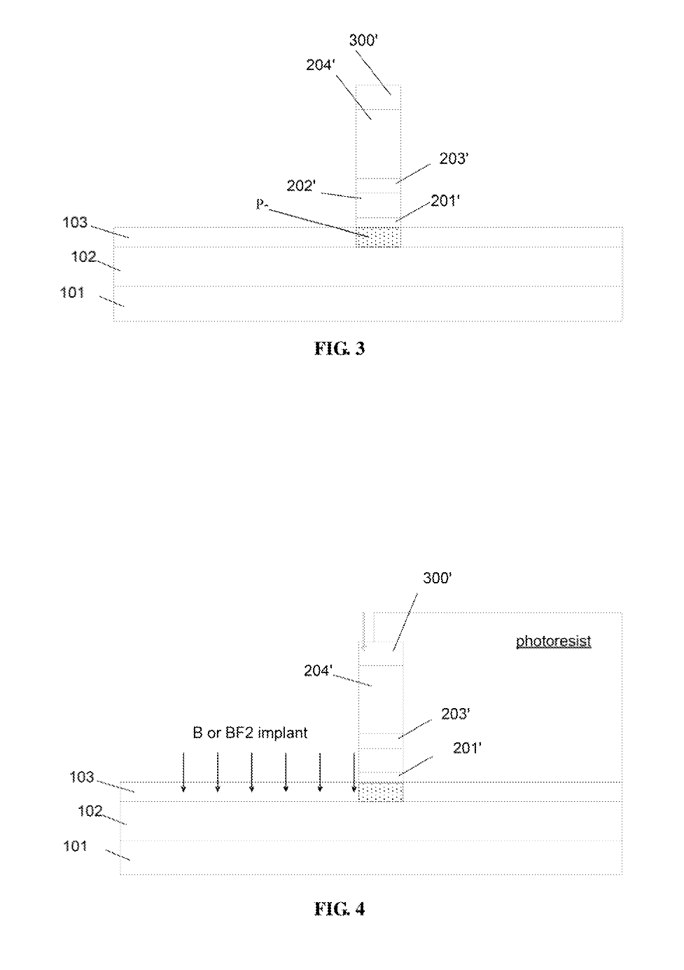

Then the gate stack structure shown in FIG. 3 is formed by a conventional etching method. Specifically, photoresist is coated on the structure shown in FIG. 2, and then a patterning process is performed to the photoresist according to the pattern of the gate stack which will be formed. At last, the gate stack structure is formed by etching according to the patterned photoresist. The gate stack structure after being etched includes a first gate dielectric layer 201′, a first conductive layer 202′, a second gate dielectric layer 203′, and a second conductive layer 204′. An oxide cap layer 300′ is further formed on the gate stack structure after the etching process.

Referring to the gate stack structure shown in FIG. 3, the first conductive layer 202′ serves as a floating gate of the flash memory device, and the second conductive layer 204′ serves as a control gate of the flash memory device. Charges on the floating gate can be erased and written by controlling voltage of the control gate.

Then, source/drain implantation is performed. Referring to FIG. 4, B, BF₂ or the like is implanted at one side of the gate with another side being covered with photoresist for protection, so as to form a p-type heavily doped region. The gate stack structure may be protected from being p-type doped with the protection of the oxide cap layer 300′ on the gate stack.

The photoresist and the oxide cap layer 300′ for protection are removed.

Then, referring to FIG. 5, As or P is implanted at the un-doped side of the gate with the heavily p-type doped region being protected by photoresist, so as to form a heavily n-type doped region. Lacking the protection of the oxide cap layer, the polysilicon on the second conductive layer 204′ on top of the gate stack structure is n-type doped, which is the same doping configuration as that of the right side. Then, the photoresist which is used for protecting is removed.

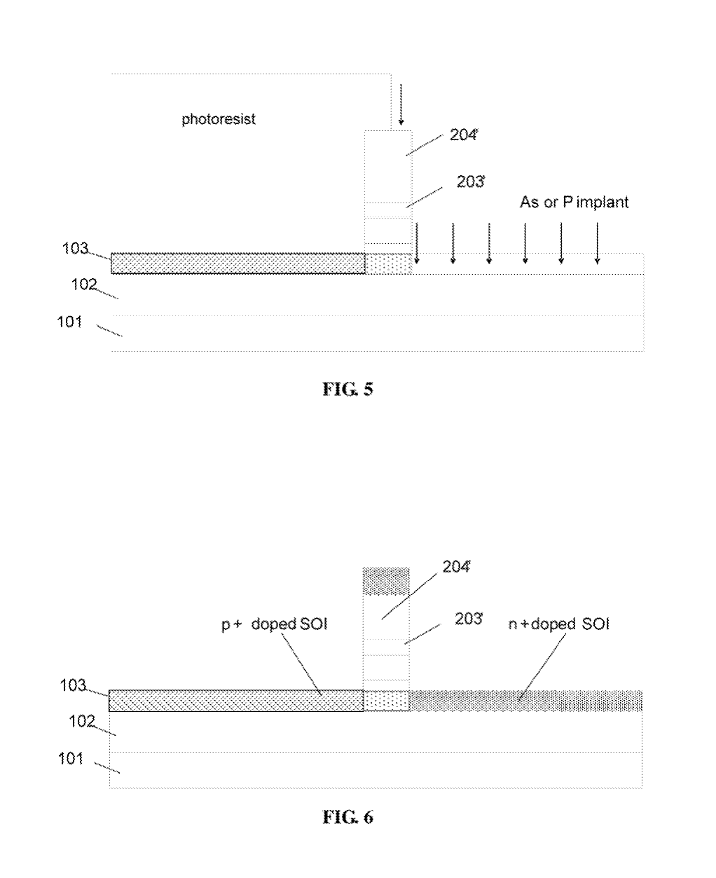

Up to now, the structure shown in FIG. 6 is formed. A heavily n-type doped (n+ in the figure) region and a heavily p-type doped (p+ in the figure) region are formed at both sides of the gate stack.

It should be noted that the doping type of the second conductive layer 204′ is opposite to that of the lightly doped channel region. Therefore, if the channel region is lightly n-type doped, the second conductive layer 204′ is p-type doped.

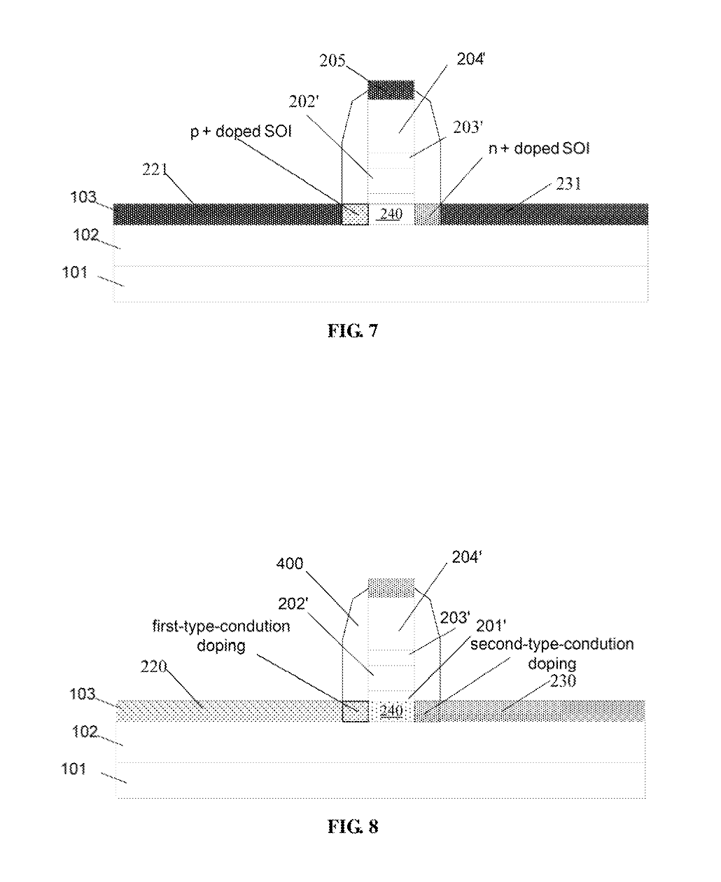

In order to activate dopants in the heavily n-type doped conductive region and the heavily p-type doped conductive region, a conventional annealing method is performed, so as to form the source region 220 and the drain region 230. Referring to FIG. 7, a spacer 400 is formed at both sides of the gate stack to separate the gate stack structure from other structures. Optionally, metal silicide contacts 221, 231 and 205 are formed on the source region 220, the drain region 230 and the control gate for better contact between the source/drain regions and the control gate. The metal silicide contacts can be formed by depositing a layer of Ni, Co or Ti on the source/drain regions and the gate and then performing rapid annealing to form silicide. The metal silicide contacts may contribute to decrease of the contact resistance.

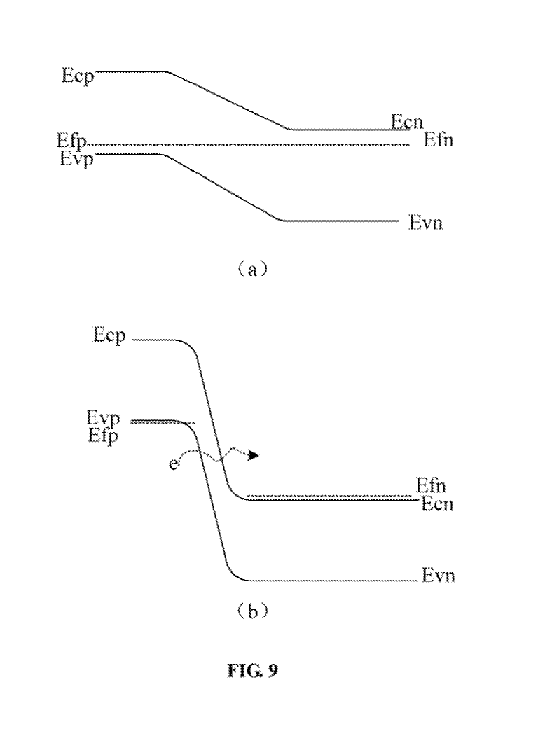

Here a semiconductor structure according to an embodiment of the present invention is formed. Referring to FIG. 8; the semiconductor structure includes a semiconductor substrate 101; and a flash memory device formed on the semiconductor substrate 101.

The flash memory device includes a gate stack, and a heavily doped first-conduction-type region 220 and a heavily doped second-conduction-type region 230.

The gate stack includes: a channel region 240 which is formed on the semiconductor 101 and may be either first-conduction-type lightly doped or second-conduction-type lightly doped; a first gate dielectric layer 201′ formed on the channel region 240; a first conductive layer 202′ formed on the gate dielectric layer 201′; a second gate dielectric layer 203′ formed on the first conductive layer 202′; a second conductive layer 204′ formed on the second gate dielectric layer 203′ which has a doping type opposite to that of the channel region 204.

The heavily doped first-type-conduction region 220 and the heavily doped second-type-conduction region 230 are located at both sides of the channel region 240, respectively, and serve as source/drain regions of the flash memory device. The first conduction type region is opposite to the second conduction type.

Preferably, the first gate dielectric layer 201′ or the second gate dielectric layer 203′ can be made of at least one of materials such as Al₂O₃, HfO₂, HfSiO, HfSiON, HfTaO, HtTiO, HfZrO, SiO₂ and Si₃N₄.

Preferably, the first conductive layer 202′ can be made of at least one of materials such as TiN, TaN, Ti, Ta, Al, Cu, Ci, Ni and polysilicon. The second conductive layer 204′ can be made of heavily doped first-conduction-type polysilicon or heavily doped second-conduction-type polysilicon.

In the embodiment of the present invention, if the first conduction type is p-type, the second conduction type is n-type, then a semiconductor structure as illustrated in FIG. 7 may be achieved according to the embodiment of the present invention. Moreover, the first conduction type may be n-type, and the second conduction type may be p-type.

Preferably, a BOX layer 102 may be formed on the semiconductor substrate 101, an SOI layer 103 may be formed on the BOX layer 102, and a channel region 240 may be formed on the SOI layer 103. Preferably, the SOI layer 103 may have a thickness within the range of about 1-10 nm, more preferably, about 5-10 nm.

Referring to FIG. 7, according to the embodiment of the present invention, metal silicide contacts 221 and 231 are further formed on the source region 220 and the drain region 230, and a metal silicide layer 205 is formed on the gate stack.

The embodiment of the present invention is based on the quantum tunneling theory. The following description is given on the assumption that, referring to the structure in FIG. 7, the left side of the structure is a p+ region, the channel region in the middle is a p− region, and the right side is a n+ region (where p+ and n+ herein indicate a heavily doped p-type region and a heavily doped n-type region, respectively, and p− indicates a lightly doped p-type region). FIG. 9 is a diagram of the energy band from the p-channel region to the n+ region at right side. For a common Tunneling Field Effect Transistor (TFET), in a case where the gate-bias is not applied, the diagram for energy bands of the channel region and portions at both sides thereof is referred to FIG. 9(a), where Ecp is a conduction band of the p− junction at the left side, Evp is a valence band of the p− junction, Ecn is a conduction hand of the n+ junction, Evn is a valence band of the n+ junction, Efp is the fermi level of the p− junction, and Efn is the fermi level of the n+ junction. If a certain negative voltage is applied to the gate, electrons will pass through the potential barrier which has been weaken, and tunneling current is formed due to the quantum tunneling effect. In the embodiment of the present invention, the Tunneling Field Effect Transistor (TFET) is integrated with a flash memory device. A large amount of negative electrons are captured in the floating gate 202′, thus Ecp and Evp will increase further, and the potential barrier will be weaken further, which is more favorable for transition of electrons. Therefore, in the embodiment of the present invention, a smaller threshold voltage can be achieved. In the embodiment of the present invention, voltage to the floating gate can be controlled by modulating the tunneling current by way of the gate voltage, and thus charges on the floating gate can be erased and written.

Although the present invention has been disclosed as above with reference to preferred embodiments thereof, the present invention is not limited thereto. Those skilled in the art can modify and vary the embodiments without departing from the spirit and scope of the present invention. Accordingly, any simply modification, equivalent changes and alternation to this embodiment which are on the base of technical substances of this invention shall be defined in the appended claims.

Embodiments described in the specification of the present invention are progressively presented. The description for each embodiment is focused on the difference from other embodiments. The description for the same or similar parts of these embodiments may be referred between embodiments. The embodiments are disclosed so that those skilled in this art may use or achieve the present invention. Various modifications to the present invention are apparent for those skilled in this art. General rules defined in this invention can also be achieved in other embodiments without departing from the scope and spirit of the present invention. Accordingly, the present invention will not he limited to the embodiments disclosed herein. Instead, the scope of the invention is defined by the appended claims as widely as possible which are in compliance with the concept and novelty disclosed herein.

1. A semiconductor structure, comprising:
a semiconductor substrate; and
a flash memory device formed on the semiconductor substrate;
wherein the flash memory device comprises:
a channel region formed on the semiconductor substrate;
a gate stack formed on the channel region, wherein the gate stack comprises: a first gate dielectric layer formed on the channel region: a first conductive layer formed on the first gate dielectric layer; a second gate dielectric layer formed on the first conductive layer; and a second conductive layer formed on the second dielectric layer; and
a heavily doped first-type-conduction region and a heavily doped second-type-conduction region at both sides of the channel region, respectively, wherein the first conduction type is opposite to the second conduction type.

2. The semiconductor structure according to claim 1, wherein the first gate dielectric layer and the second gate dielectric layer are made of at least one of Al₂O₃, HfO₂, HfSiO, HfSiON, HfTaO, HfTiO, HfZrO, SiO₂ and Si₃N₄.

3. The semiconductor structure according to claim 1, wherein the first conductive layer is made of at least one of TiN, TaN, Ti, Ta, Al, Cu, Ci, Ni and polysilicon.

4. The semiconductor structure according to claim 1, wherein conduction type of the second conductive layer is opposite to that of the channel region.

5. The semiconductor structure according to claim I, wherein the first conduction type is p-type, the second conduction type is n-type, and the second conductive layer is a heavily doped second-conduction-type polysilicon.

6. The semiconductor structure according to claim 1, wherein the first conduction type is n-type, the second conduction type is p-type, and the second conductive layer is a heavily doped second-conduction-type polysilicon.

7. The semiconductor structure according to claim 1, wherein a SOI layer is formed on the semiconductor substrate, and the channel region is formed on the SOI layer.

8. The semiconductor structure according to claim 7, wherein a buried oxide layer is formed on the semiconductor layer, and the SOI layer is formed on the buried oxide layer.

9. The semiconductor structure according to claim 7, wherein the SOI layer has a thickness within the range of about 1-10 nm.

10. A method for manufacturing a semiconductor structure, comprising:
providing a semiconductor substrate;
forming a gate stack on the semiconductor substrate, wherein the gate stack comprises: a first gate dielectric layer formed on the semiconductor substrate; a first conductive layer formed on the first gate dielectric layer; a second gate dielectric layer formed on the first conductive layer; and a second conductive layer formed on the second gate dielectric layer; and
performing heavy doping in the semiconductor substrate at both sides of the gate stack to form a first-conduction-type region and a second-conduction-type region, wherein the first conduction type is opposite to the second conduction type.

11. The method for manufacturing a semiconductor structure according to claim 10, wherein the first conductive layer is made of at least one of TiN, TaN, Ti, Ta, Al, Cu, Ci, Ni and polysilicon.

12. The method for manufacturing a semiconductor structure according to claim 10, wherein the first gate dielectric layer and the second gate dielectric layer are made of at least one of Al₂O₃, HfO₂, HfSiO, HfSiON, HMO, HfTiO, HfZra SiO₂ and Si₃N₄.

13. The method for manufacturing a semiconductor structure according to claim 12, wherein before or after the gate stack is formed, the method further comprises:
performing doping with the first-conduction-type ions in the channel region beneath the gate stack; and
performing heavily doping in the second conductive layer on the gate stack to form a second-conduction-type conductive layer when forming the second-conduction-type region, wherein the second conductive layer is made of polysilicon.

14. The method for manufacturing a semiconductor structure according to claim 10, wherein the first conduction type is p-type, and the second conduction type is n-type.

15. The method for manufacturing a semiconductor structure according to claim 10, wherein the first conduction type is n-type, and the second conduction type is p-type.

16. The method for manufacturing a semiconductor structure according to claim 10, wherein before the gate stack is formed, the method further comprises: forming a SOT layer on the semiconductor substrate.

17. The method for manufacturing a semiconductor structure according to claim 16, wherein before the SOI layer is formed, the method further comprises: forming a buried oxide layer on the semiconductor substrate.

18. The method for manufacturing a semiconductor structure according to claim 16, wherein the SOI layer has a thickness within the range of about 1-10 nm.
